(19) United States
(12) Patent Application Publication
(10) Pub. No.: US 2012/0292789 A1
(43) Pub. Date: Nov. 22, 2012

(54) SEMICONDUCTOR WAFER AND METHOD OF PRODUCING THE SAME

(75) Inventor: Hiroyuki SAZAWA, Ibaraki (JP)

(73) Assignee: SUMITOMO CHEMICAL COMPANY, LIMITED, Tokyo (JP)

(21) Appl. No.: 13/479,834

(22) Filed: May 24, 2012

Related U.S. Application Data
(63) Continuation-in-part of application No. PCT/JP2010/006871, filed on Nov. 25, 2010.

(30) Foreign Application Priority Data
Nov. 26, 2009 (JP) 2009-268523

(51) Int. Cl. H01L 23/544; H01L 21/02

(52) U.S. Cl. 257/797; 438/401; 257/E23.179; 257/E21.002

(57) ABSTRACT

Provided is a method of producing a semiconductor wafer. The method includes forming an alignment mark on a base wafer, forming, on the base wafer in a region that includes the alignment mark, an inhibition layer for inhibiting crystal growth after forming the alignment mark, forming, in a region of the inhibition layer where no alignment mark is provided, an opening in which the base wafer is exposed, on the basis of information that indicates a location where the opening is to be formed with reference to the position of the alignment mark, and growing a semiconductor crystal inside the opening.

### BACKGROUND

1. Technical Field

The present invention relates to a semiconductor wafer and a method of producing a semiconductor wafer. The contents of the following Japanese patent application and PCT patent application are incorporated herein by reference:
JP2009-268523 filed on Nov. 26, 2009, and
PCT/JP2010/006871 filed on Nov. 25, 2010.

2. Related Art

A technique to selectively grow GaN on an AlN buffer layer provided on a Si wafer has been known (see, for example, Non-patent Document 1). A technique to grow a semiconductor crystal using alignment marks that are formed on a semiconductor wafer has also been known (for example, see Patent Document 1). The above mentioned Non-patent Document 1 is S. Haffouz, et. al., Journal of crystal growth, 311(2009)2087-2090, and Patent Document 1 is JP-A-10-64781.

### SUMMARY

In a manufacturing process for electronic and optical devices using a photolithography method, functional crystal is firstly grown on the whole surface of a base wafer. Alignment marks are then formed on the functional crystal using a notch or orientation flat that has been previously provided on the base wafer as a mechanical guide. Subsequently, functional members such as electrodes and metal wiring are formed such that they are aligned on the functional crystal with reference to the formed alignment marks. Through the above mentioned process, electronic and optical devices having functional crystal are formed.

However, when functional crystal is formed on a part of the base wafer instead of the whole surface of the base wafer using a notch or orientation flat as a mechanical guide and then the alignment marks are formed, there may be the following drawbacks. Notches or orientation fiat have low alignment accuracy as a mechanical guide, and therefore it is difficult to form the functional crystal partially on the base wafer such that it precisely aligns on the base wafer. It is also difficult to form alignment marks on the base wafer or the fictional crystal with high alignment accuracy with respect to the base wafer. As a result, the functional members formed and aligned with reference to the alignment marks cannot be arranged with high alignment accuracy with respect to the functional crystal. This problem becomes more apparent as the size of the functional crystal is made smaller.

In order to address such problem, after the alignment mark is formed, a difference in position between the alignment mark and the functional crystal is measured, and photolithography is then performed with positional correction based on the measured difference. In this way, it is possible to arrange the functional members such as electrodes and metal wiring with high alignment accuracy. However, this technique increases the number of processes, resulting in low productivity and cost, increase. Particularly in the current semiconductor processes, many semiconductor wafers are automatically and sequentially processed according to takt time (a time cycle required for a single work) which is typically several tens of seconds. Therefore, if each wafer is measured, its positional correction value is estimated and then the position in which the functional member is formed is corrected, the productivity is significantly decreased and it leads to cost increase.

When a semiconductor crystal is grown on a semiconductor wafer, the semiconductor crystal is grown also in the alignment marks, and consequently image recognition of the edges of the alignment marks is made less easy. Therefore, it becomes difficult to detect the alignment marks with high accuracy, the semiconductor crystal within the alignment marks should be removed in the case where the functional members such as electrodes and metal wiring are to be provided on the semiconductor crystal. If the semiconductor crystal within the alignment marks is not removed, it is necessary to form new alignment marks.

In order to overcome the above drawbacks accompanying the related art, a first aspect of the innovations may provide a method of producing a semiconductor wafer. The method includes forming an alignment mark on a base wafer; forming, on the base wafer in a region that includes the alignment mark, an inhibition layer for inhibiting crystal growth after forming the alignment mark; forming, in a region of the inhibition layer where no alignment mark is provided, an opening in which the base wafer is exposed, on the basis of information that indicates a location where the opening is to be formed with reference to the position of the alignment mark; and growing a semiconductor crystal inside the opening. The method may further include forming at least one of an electrode and a metal wiring line on the semiconductor crystal with reference to the position of the alignment mark.

In the forming of the opening, a plurality of the openings may be formed in the region of the inhibition layer where no alignment mark is provided, In the forming of the opening, the plurality of openings may be formed on the basis of information that indicates locations where the plurality of openings are to be formed with reference to the position of the alignment mark.

In the growing of the semiconductor crystal, the semiconductor crystal may be grown in each of the plurality of openings, The method may further include forming a functional member that includes at least one of an electrode and a metal wiring line over the semiconductor crystal in each of the plurality of openings with reference to the position of the alignment mark. In the forming of the functional member, the functional member is formed by, for example, lithography with reference to the position of the alignment mark.

The base wafer used in the method is, for example, a wafer whose surface is made of a silicon crystal, a wafer whose surface is made of a germanium crystal, or a Group 3-5 compound semiconductor wafer. In the growing of the semiconductor crystal, for example, a Group 3-5 compound semiconductor crystal or a Group 2-6 compound semiconductor crystal is grown. The growing of the semiconductor crystal may include growing a first semiconductor crystal having a composition of 6Cₓ₁Si_{y1}Ge_{z1}Sn_{1-x1-y1-z1} (0≦x1<1, 0≦y1≦1, 0≦z1≦1, and 0<x1+y1+z1≦1), and growing a second semiconductor crystal directly or indirectly on the first semiconductor crystal. The inhibition layer formed in the method includes, for example, any of silicon oxide, silicon nitride, silicon oxynitride, or aluminum oxide.

In the forming of the alignment mark, the alignment mark is formed on the base wafer by, for example, etching the base wafer. In the forming of the alignment mark, the alignment mark may be formed on the base wafer by forming, on the base wafer, at least one metal selected from the group consisting of tantalum, niobium, nickel, tungsten, and titanium.

A second aspect of the innovations may provide a semiconductor wafer including a base wafer on which an alignment mark is formed, a first inhibition layer that inhibits crystal growth and is provided on the base wafer in a region other than a region where the alignment mark is formed, the first inhibition layer having an opening in which the base wafer is exposed, a second inhibition layer that inhibits crystal growth and is provided, over the alignment mark; and a semiconductor crystal that is grown inside the opening. The first inhibition layer may have a plurality of the openings, and the semiconductor wafer may have the semiconductor crystal grown in each of the plurality of openings.

For example, the thickness of the base wafer at the position of the alignment mark is different from the thickness of the base wafer in a region of the base wafer other than the position of the alignment mark, and the distance between a back surface of the base wafer and a first surface of the first inhibition layer is different from the distance between the back surface of the base wafer and a first surface of the second inhibition layer, wherein the back surface of the base wafer opposes a surface of the base wafer that is in contact with the first inhibition layer, the first surface of the first inhibition layer opposes a second surface of the first inhibition layer that is closer to the base wafer, and the first surface of the second inhibition layer opposes a second surface of the second inhibition layer that is closer to the base wafer. The thickness of the base wafer at the position of the alignment mark may be smaller than the thickness of the base wafer in the region of the base wafer other than the position of the alignment mark, and the distance between the back surface of the base wafer and the first surface of the first inhibition layer may be larger than the distance between the back surface of the base wafer and the first surface of the second inhibition layer.

The thickness of the base wafer at the position of the alignment mark may be larger than the thickness of the base wafer in the region of the base wafer other than the position of the alignment mark, and the distance between the back surface of the base wafer and the first surface of the first inhibition layer is smaller than the distance between the back surface of the base wafer and the first surface of the second inhibition layer.

The summary clause does not necessarily describe all necessary features of the embodiments of the present invention. The present invention may also be a sub-combination of the features described above.

### BRIEF DESCRIPTION OF THE DRAWINGS

FIG. 1A shows a sectional view of a semiconductor wafer 100 according to an embodiment of the invention.

FIG. 1B shows a plan view of the semiconductor wafer 100.

FIG. 2 shows a sectional view of a semiconductor wafer 200 according to the embodiment of the invention.

FIG. 3 shows a sectional view of a semiconductor wafer 300 according to another embodiment of the invention.

FIG. 4 shows a sectional view of a semiconductor wafer 400 according to another embodiment of the invention.

FIG. 5 shows a sectional view of a semiconductor wafer 500 according to another embodiment of the invention.

FIG. 6A illustrates a method of manufacturing the semiconductor wafer 200.

FIG. 6B illustrates the method of manufacturing the semiconductor wafer 200.

FIG. 6C illustrates the method of manufacturing the semiconductor wafer 200.

FIG. 7 is a sectional view of a manufactured semiconductor wafer 700.

FIG. 8 illustrates a shape of an alignment mark 720 formed on the semiconductor wafer 700.

FIG. 9 is a sectional view of a manufactured semiconductor wafer 900.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

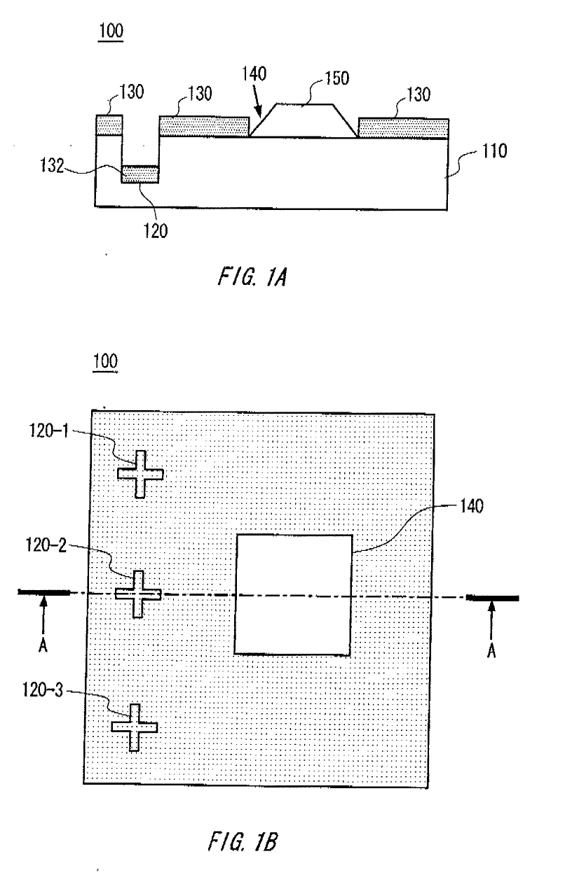

FIG. 1A shows a sectional view of a semiconductor wafer 100 according to an embodiment of the invention. FIG. 1B shows a plan view of the semiconductor wafer 100. FIG. 1A is a sectional view along the line A-A in FIG. 1B.

The semiconductor wafer 100 includes a base wafer 110, an inhibition layer 130, an inhibition layer 132 and a semiconductor crystal 150. An alignment mark 120 is formed on the base wafer 110. The alignment mark 120 is formed by, for example, etching a partial region of the base wafer 110.

The base wafer 110 is, for example, a wafer whose surface is made of a silicon crystal, a wafer whose surface is made of a germanium crystal, or a Group 3-5 compound semiconductor wafer. Here, “a wafer whose surface is made of a silicon crystal” means that the wafer has a region in which the surface of the wafer is made of silicon crystal. An example of such wafer whose surface is made of silicon crystal includes a Si wafer the whole of which is made of silicon crystal and a silicon-on-insulator (SOI) wafer.

Here, “a wafer whose surface is made of a germanium crystal” means that the wafer has a region in which the surface of the wafer is made of germanium crystal. An example of such wafer whose surface is made of a germanium crystal includes a Ge wafer the whole of which is made of germanium crystal and a germanium-on-insulator (GOI) wafer. Here, “a Group 3-5 compound semiconductor wafer” refers to a wafer made of a Group 3-5 compound semiconductor. An example of such Group 3-5 compound semiconductor wafer includes a GaAs wafer.

When the surface of the base wafer 110 is made of silicon crystal, a main plane of the base wafer 110 that is in contact with the inhibition layer 130 is, for example, the plane (100), the plane (110), the plane (111), a plane equivalent to the plane (100), a plane equivalent to the plane (110) or a plane equivalent to the plane (111). The main plane of the base wafer 110 may be slightly tilted away from the above-mentioned crystallographically-defined plane orientation. In other words, the base wafer 110 may have an off angle.

The inhibition layer 130 is provided on the base wafer 110 in a region other than the region where alignment mark 120 is formed. The inhibition layer 130 has an opening 140 in which the base wafer 110 is exposed. The opening 140 is formed by, for example, etching a part of the inhibition layer 130. The inhibition layer 130 inhibits growth of the semiconductor crystal 150. For example, as shown in FIG. 1A, the semiconductor crystal 150 is grown inside the opening 140 but is not grown on the inhibition layer 130.

The inhibition layer 132 is provided on the alignment mark 120 and inhibits crystal growth. The semiconductor crystal 150 is also not grown on the inhibition layer 132.

For example, the inhibition layer 130 and the inhibition layer 132 include silicon oxide, silicon nitride, silicon oxynitride, or aluminum oxide. The inhibition layer 130 and the inhibition layer 132 may be formed by depositing any of silicon oxide, silicon nitride, silicon oxynitride, or aluminum oxide. The inhibition layer 132 is preferably transparent. When the inhibition layer 132 is preferably transparent, light illuminated from the upper side of the semiconductor wafer 100 can be transmitted through the inhibition layer 132 and reaches to the bottom of the alignment mark 120, and therefore it is possible to detect the alignment mark 120 with high accuracy.

The semiconductor crystal 150 is, for example, a Group 3-5 compound semiconductor or a Group 2-6 compound semiconductor. A Group 3-5 compound semiconductor layer includes, for example, at least one of Al, Ga and In as a Group 3 element, and at least one of N, P, As and Sb as a Group 5 element. The semiconductor crystal 150 is, for example, GaN. The semiconductor crystal 150 is used in, for example, LEDs, bipolar-transistors and field-effect transistors as a semiconductor crystal in a region where electrons and holes are transferred.

The semiconductor crystal 150 is preferably lattice-matched or pseudo-lattice-matched to the base wafer 110. Here, “pseudo-lattice-matched” means the state which is not a perfect lattice matching but in which a difference in the lattice constant between two contacting semiconductors is small and the two contacting semiconductors can be disposed on top of each other to the extent where defects due to lattice mismatch are less represented. For instance, the state in which a Si layer and a GaN layer stack each other is the state in which the Si layer and the GaN layer are pseudo-lattice-matched.

The thickness of the base wafer 110 at the position where the alignment mark 120 exists is different from thicknesses of the base wafer 110 in region of the base wafer 110 other than the region where the alignment mark 120 is provided. Since the thickness of the base wafer 110 at the position where the alignment mark 120 exists is different from thicknesses of the base wafer 110 at positions where no alignment mark 120 is provided on the base wafer 110, it is possible to detect the positions of the alignment marks by an image recognition apparatus using an optical microscope. For example, the position of the alignment mark 120 can be detected on the basis of reflected light that is generated when the base wafer 110 is illuminated from above. More specifically, boundaries of the alignment mark 120 can be detected on the basis of difference in the amount of reflected light between when the alignment mark 120 or the region where no alignment mark 120 is provided is illuminated and when the boundaries of the alignment mark 120 are illuminated.

The distance between a back surface of the base wafer 110 and a first surface of the inhibition layer 130 is different from the distance between the back surface of the base wafer 110 and a first surface of the inhibition layer 132. Here, the back surface of the base wafer 110 opposes a surface of the base wafer 110 that is in contact with the first inhibition layer, the first surface of the inhibition layer 130 opposes a second surface of the inhibition layer 130 that is closer to the base wafer 110, and the first surface of the inhibition layer 132 opposes a second surface of the inhibition layer 132 that is closer to the base wafer 110. According to the embodiment, even when the inhibition layer 132 is formed within the alignment mark 120, the surface level of the inhibition layer 130 is different from the surface level of the inhibition layer 132, and thereby the boundary lines of the alignment mark 120 remain. Consequently, the position of the alignment mark 120 can be detected by illuminating the base wafer 110 from above.

Referring to FIG. 1A, when the alignment mark 120 is formed by etching a part of the base wafer 110, the thickness of the base wafer 110 at the position of the alignment mark 120 is smaller than thicknesses of the base wafer 110 in the region where no alignment mark 120 is provided on the base wafer 110. In addition, the distance between the back surface of the base wafer 110 and the first surface of the inhibition layer 130 is larger than the distance between the back surface of the base wafer 110 and the first surface of the inhibition layer 132. Here, the back surface of the base wafer faces away from the inhibition layer 130, the first surface of the inhibition layer 130 faces away from the base wafer 110, and the first surface of the inhibition layer 132 faces away from the base wafer 110.

The alignment mark 120 may have any shape. As shown in FIG. 1B, the alignment mark 120 has, for example, a cross-like figure. A line connecting the center of at least one alignment mark 120 with the center of the opening 140 is, for example, parallel or perpendicular to sides of the surface of the base wafer 110 exposed in the opening 140. When the alignment mark 120 is projected against the main plane of the base wafer 110, the lines composing the profile of the alignment mark 120 are each, for example, parallel or perpendicular to sides of the surface of the base wafer 110 exposed in the opening 140.

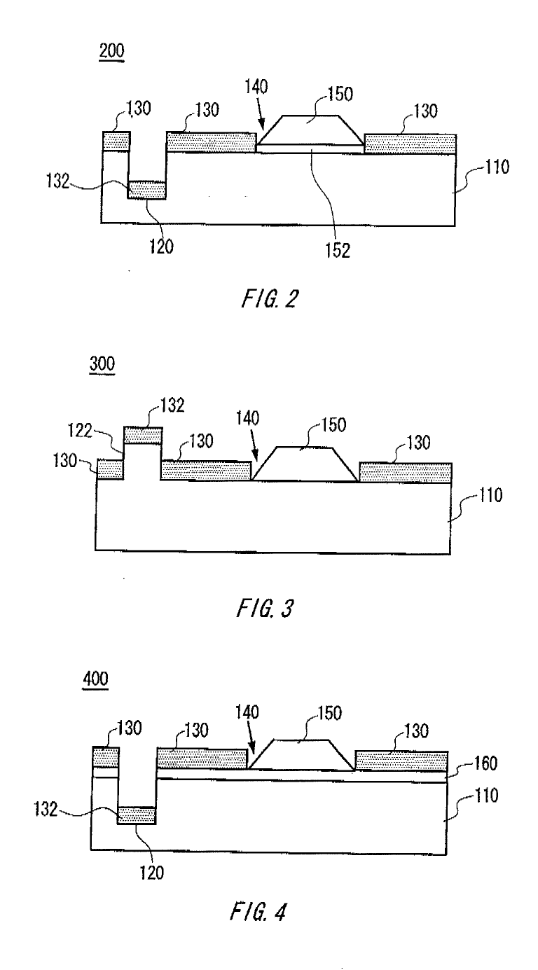

FIG. 2 shows a sectional view of a semiconductor wafer 200 according to the embodiment of the invention. The semiconductor wafer 200 is different from the semiconductor wafer 100 illustrated in FIG. 1A in that it has a buffer layer 152 between the semiconductor crystal 150 and the base wafer 110. The opening 140 exposes the buffer layer 152. The lattice constant of the buffer layer 152 falls within a range between the lattice constant of the base wafer 110 and the lattice constant of the semiconductor crystal 150. The buffer layer 152 is made of, for example, a Group 3-5 compound semiconductor or a Group 4 compound semiconductor. The buffer layer 152 may be made of a Group 3 nitride semiconductor.

For instance, when the surface of the base wafer 110 is made of Si and the semiconductor crystal 150 is Group 3-5 compound semiconductor crystal or Group 2-6 compound semiconductor crystal, the buffer layer 152 has a composition of Cₓ₁Si_{y1}Ge_{z1}Sn_{1-x1-y1-z1} (0≦x1<1, 0≦y1≦1, 0≦z1≦1, and 0<x1+y1+z1≦1). The buffer layer 152 prevents defects in the semiconductor crystal 150 caused due to a difference in the lattice constant between the semiconductor crystal 150 and the base wafer 110. More specifically, the buffer layer 152 can reduce the chances of defects generated between the base wafer 110 and the buffer layer 152, moreover, the buffer layer 152 can reduce the chances of defects generated between the buffer layer 152 and the semiconductor crystal 150. The buffer layer 152 may mitigate warpage of the base wafer 110 due to a difference in the coefficient of thermal expansion between the base wafer 110 and the semiconductor crystal 150.

FIG. 3 shows a sectional view of a semiconductor wafer 300 according to another embodiment of the invention. An alignment mark 122 shown in FIG. 3 is different from the alignment mark 120 formed on the semiconductor wafer 100 shown in FIG. 1A in that it is formed by depositing metal in a part of region on the base wafer 110. The metal deposited here is at least one metal selected from the group consisting of tantalum, niobium, nickel, tungsten, and titanium.

Referring to FIG. 3, the thickness of the base wafer 110 at the position of the alignment mark 122 is larger than thicknesses of the base wafer 110 in the regions where no alignment mark 122 is provided on the base wafer 110. The distance between the back surface of the base wafer 110 and the first surface of the inhibition layer 130 is smaller than the distance between the back surface of the base wafer 110 and the first surface of the inhibition layer 132. Here, the back surface of the base wafer faces away from the inhibition layer 130, the first surface of the inhibition layer 130 faces away from the base wafer 110, and the first surface of the inhibition layer 132 faces away from the base wafer 110. Referring again to FIG. 3, when the alignment mark 122 is formed by depositing metal, it is also possible to detect the position of the alignment mark 122 by illuminating the base wafer 110 from above.

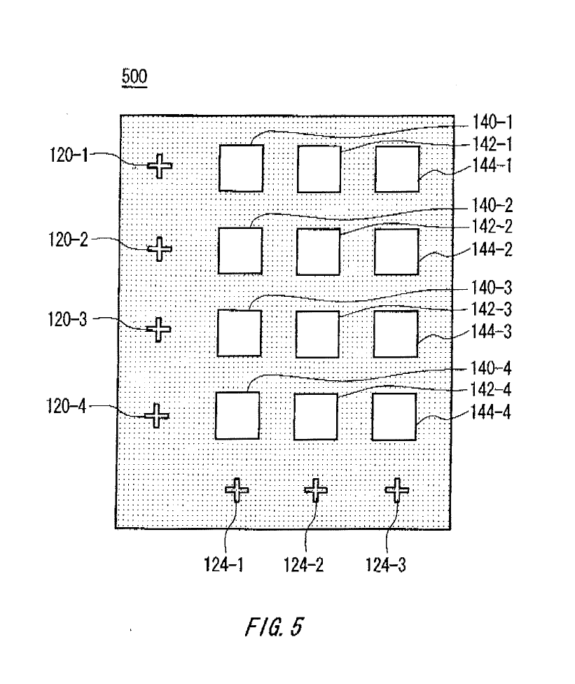

FIG. 4 shows a sectional view of a semiconductor wafer 400 according to another embodiment of the invention. The semiconductor wafer 400 shown in FIG. 4 is different from the semiconductor wafer 100 shown in FIG. 1A in that it has a buffer layer 160 between the base wafer 110 and the inhibition layer 130. Since the semiconductor wafer 400 has the buffer layer 160, it is possible to reduce the number of crystal faults generated due to a difference in the lattice constant between the base wafer 110 and the semiconductor crystal 150. When the surface of the base wafer 110 is made of silicon and the semiconductor crystal 150 is gallium nitride, the buffer layer 160 is made of, for example, aluminum nitride,

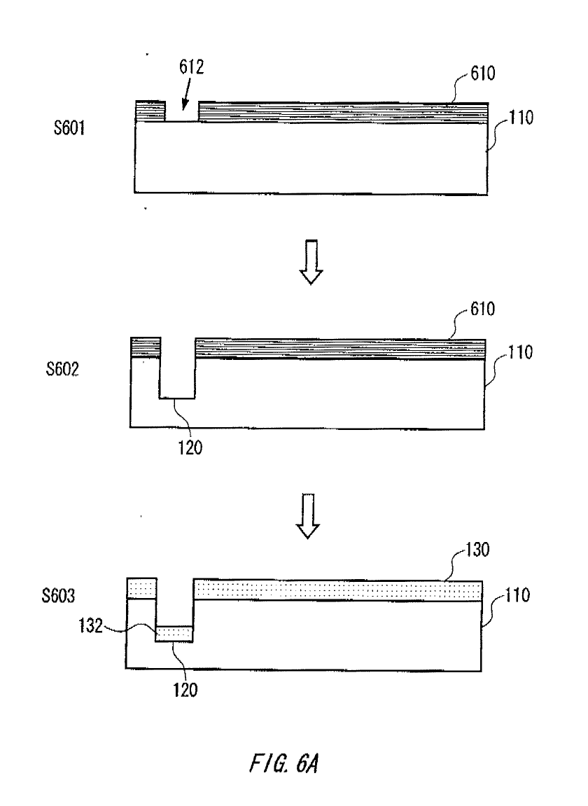

FIG. 5 shows a sectional view of a semiconductor wafer 500 according to another embodiment of the invention. In the semiconductor wafer 500, the inhibition layer 130 has a plurality of openings 140-n, 142-n and 144-n (where n is an integer from 1 to 4). The semiconductor wafer 500 has the semiconductor crystal 150 which is grown in each of the plurality of the openings 140.

For example, the plurality of openings 140-n, 142-n and 144-n are arranged in a lattice pattern. In other words, an opening 140-1, an opening 140-2, an opening 140-3, and an opening 140-4 are arranged in a straight line in a first direction at a first interval. In the same manner, an opening 142-1, an opening 142-2, an opening 142-3, and an opening 142-4 are arranged in a straight line in the first direction at the first interval. In the same manner, an opening 144-1, an opening 144-2, an opening 144-3, and an opening 144-4 are arranged in a straight line in the first direction at the first interval.

Moreover, the opening 140-1, the opening 142-1, and the opening 144-1 are arranged in a straight line in a second direction at a second interval. The second direction is perpendicular to the first direction. In the same manner, the opening 140-2, the opening 142-2, and the opening 144-2 are arranged in a straight line in the second direction at the second interval. In the same manner, the opening 140-3, the opening 142-3, and the opening 114-3 are arranged in a straight line in the second direction at the second interval. The first interval and the second interval may be identical.

The semiconductor wafer 500 has more than one alignment mark 120 and more than one alignment mark 122. For example, the semiconductor Wafer 500 has an alignment mark 120-1, an alignment mark 120-2, an alignment mark 120-3, and an alignment mark 120-4 which are arranged in line in a first direction. The semiconductor wafer 500 further has an alignment mark 124-1, an alignment mark 124-2 and an alignment mark 124-3, and an alignment mark 120-4 which are arranged in line in a second direction. The inhibition layer 132 is provided in each of the plurality of alignment marks 120 and the plurality of alignment marks 124.

For example, the semiconductor 500 has a number of the alignment marks 120 corresponding to the number of the openings 140. The semiconductor wafer 500 may have the alignment marks 124 that each correspond to one of the groups of the openings that are arranged in line in the first direction. The semiconductor wafer 500 may have the alignment marks 120 that each correspond to one of the groups of the openings that are arranged in line in the second direction.

For example, the center of the alignment mark 120-1 is arranged on the line connecting the centers of the opening 140-1, the opening 142-1 and the opening 144-1. The center of the alignment mark 124-1 is arranged on the line connecting the centers of the opening 140-1, the opening 140-2 and the opening 140-3, and the opening 140-4. By arranging the alignment mark 120 or the alignment mark 124 in this way, it is possible to increase the alignment accuracy of the semiconductor wafer 500 that has the plurality of openings.

The semiconductor wafer 500 may have the alignment marks 124 that each are provided for any number of groups of the openings that are arranged in line in the first direction. In the same manner, the semiconductor wafer 500 may have the alignment marks 120 that each are provided for any number of groups of the openings that are arranged in line in the second direction.

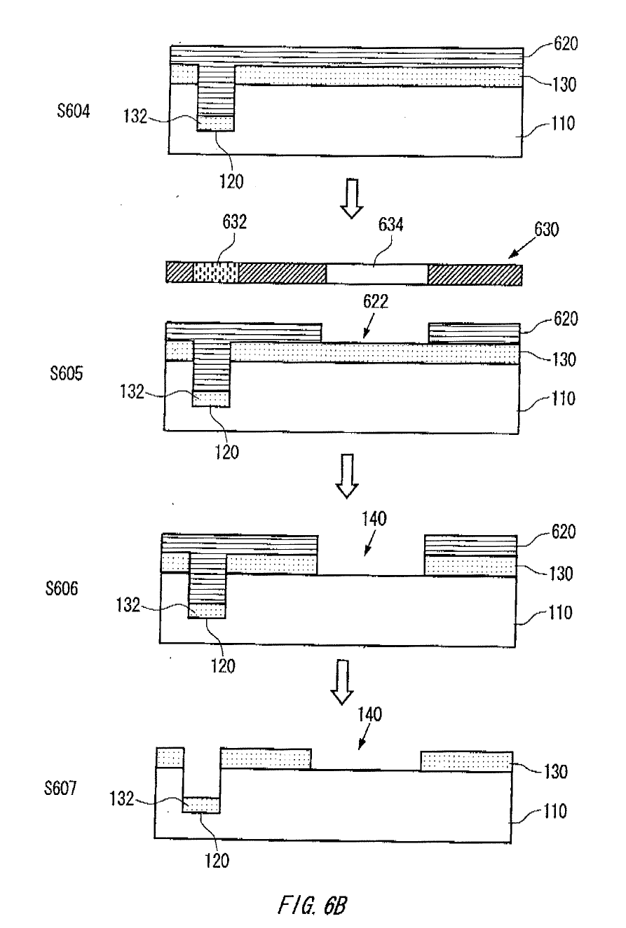

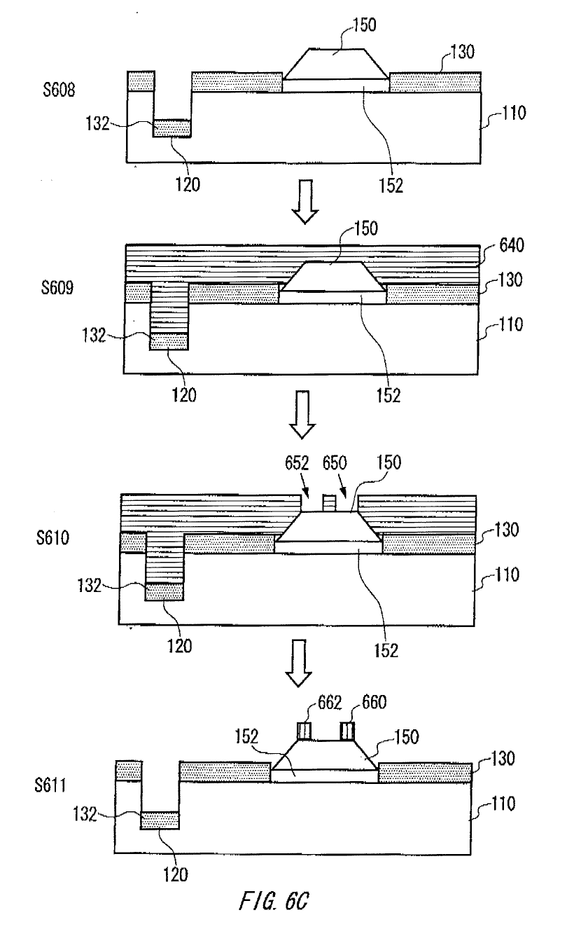

FIGS. 6A, 6B, and 6C illustrate a method of producing a semiconductor wafer 200. In S601, a photosensitive resin 610 is applied onto the base wafer 110. An opening 612 is then formed in the base wafer 110 at the position where the alignment mark 120 is to be formed by, for example, a photolithography method.

In S602, a plurality of the alignment marks 120 are formed by dry-etching the base wafer 110 using the photosensitive resin 610 in which the opening 612 is formed as a mask. Alternatively, the alignment marks 120 can be formed by irradiating the base wafer 110 with a laser light.

In S602, the alignment mark 122 shown in FIG. 3 may be formed by providing metal on the base wafer 110. The metal used here preferably has a heat resistance property against a temperature of crystal growth or a process performed later. An example of such metal includes at least one metal selected from the group consisting of tantalum, niobium, nickel, tungsten, and titanium, More specifically, such metal is deposited on the exposed surface of the base wafer 110, the metal is then processed into a prescribed shape, and the resulting metal-deposited film can be used as the alignment mark 122.

Subsequently in S603, the inhibition layer 130 and the inhibition layer 132 which inhibit crystal growth are formed on the base wafer 110 in a region including the alignment mark 120. The inhibition layer 130 and the inhibition layer 132 can be formed by, for example, a chemical vapor deposition (CVD) method, an evaporation method or a sputtering method.

In S604 shown in FIG. 6B, a photosensitive resin 620 is formed on the inhibition layer 130. When the photosensitive resin 620 is light-transmissive, the photosensitive resin 620 may be formed over the inhibition layer 132. During a formation step of the photosensitive resin 620, a wet photosensitive resin is applied onto the inhibition layer 130 by, for example, a spin-coating method. Alternatively, the photosensitive resin 620 may be formed by applying a dry photosensitive resin on the inhibition layer 130.

In S605, for example, through a photolithography method, an opening 622 is formed in the photosensitive resin 620 on the base wafer 110 in a region where no alignment mark 120 is provided. In S606, the opening 140 is formed in the region where no alignment mark 120 is provided, by etching the inhibition layer 130 using the photosensitive resin 620 as a mask. The opening 140 can be formed by, for example, wet etching using chemicals or dry etching using gas plasma. In S607, the photosensitive resin 620 is removed.

The base wafer 110 is exposed in the opening 140. A basal area of the opening 140 is 0.01 mm² or less, preferably 1,600 μm² or less, and more preferably 900 μm² or less. When the area of the opening 110 is in such range, it is possible to reduce defects generated in the semiconductor crystal 150 that grows inside the opening 140.

In S605, the opening 622 is formed on the basis of information indicating the position where the opening 140 is to be formed with reference to the position of the alignment mark 120. More specifically, a mask 630 used for photolithography is placed above the photosensitive resin 620. In the mask 630, a reference mark 632 corresponding to the alignment mark 120, and an opening 634 corresponding to the opening 140 are formed.

The mask 630 is irradiated with ultraviolet light from above while the position of the reference mark 632 formed in the mask 630 is aligned with the position of the alignment mark 120 in order to transfer the pattern of the opening 622 in the mask 630 to the photosensitive resin 620. Developing and cleaning processes are then performed, and in this way, the opening 622 is formed in the photosensitive resin 620.

In the step of aligning the position of the reference mark 632 with the position of the alignment mark 120, the position of the alignment mark 120 is detected by image recognition in which the base wafer 110 is scanned by irradiating ultraviolet light from above and analyzing a variation in the amount of reflected light. The position of the reference mark 632 can be aligned with the position of the alignment mark 120 by controlling the position of the mask 630 such that the detected position of the alignment mark 120 is brought to the position of the reference mark 632 in the mask 630.

When the position of the mask 630 is controlled, it is preferable that the mask 630 that has more than one reference mark 632 be used. It is possible to increase the positional accuracy to form the opening 140 by aligning more than one alignment mark 120 with more than one reference mark 632.

When more than one opening 140 is provided in the inhibition layer 130, a plurality of the openings 140 are formed on the basis of information indicating the positions where the plurality of openings 140 to be formed with reference to the position of the alignment mark 120. More specifically, the mask 630 has a plurality of openings 634 that are formed at positions corresponding to the plurality of openings 140. A plurality of the openings 622 can be formed in the photosensitive resin 620 so as to correspond to the plurality of openings 140 by irradiating ultraviolet light from above the mask 630.

Next in S608 shown in FIG. 6C, the buffer layer 152 is formed by crystal growth. The semiconductor crystal 150 is then grown on the buffer layer 152. In S608, it is preferable that the buffer layer 152 and the semiconductor crystal 150 be grown inside the opening 140 by an epitaxial growth method. An example of the epitaxial growth method includes a metal organic chemical vapor deposition (MOCVD) and a molecular beam epitaxy (MBE). When the inhibition layer 130 has a plurality of the openings 140, the buffer layer 152 and the semiconductor crystal 150 are grown inside each of the openings 140.

The semiconductor crystal 150 is, for example, a Group 3-5 compound semiconductor crystal or a Group 2-6 compound semiconductor crystal. The buffer layer 152 has, for example, a composition of Cₓ₁Si_{y1}Ge_{z1}Sn_{1-x1-y1-z1} (0≦x1<1, 0≦y1≦1, 0≦z1≦1, and 0<x1+y1+z1≦1).

The buffer layer 152 and the semiconductor crystal 150 are not grown on the inhibition layer 132. Accordingly, the semiconductor crystal is not grown within the alignment mark 120 while the buffer layer 152 and the semiconductor crystal 150 are grown inside the opening 140. As a result, the alignment mark 120 can be used for alignment even after the buffer layer 152 and the semiconductor crystal 150 are grown inside the opening 140.

More specifically, as illustrated in S609 through S611, an electrode 660 and an electrode 662 can be formed on the semiconductor crystal 150 with reference to the alignment mark 120, Metal wiring may be formed on the semiconductor crystal 150 with reference to the alignment mark 120. When more than one semiconductor crystal 150 are formed on the base wafer 110, a functional member including at least one of the electrode 660, the electrode 662 and metal wiring can be formed on each semiconductor crystal 150. A well region or an element isolation region can also be formed with reference to the alignment mark 120.

In S609, a photosensitive resin 640 is applied so as to cover the inhibition layer 130, the inhibition layer 132 and the semiconductor crystal 150. Subsequently in S610, an opening 650 and an opening 652 arc formed in the photosensitive resin 640 at the positions where the electrode 660 and the electrode 662 are to be formed with reference to the position of the alignment mark 120. The opening 650 and the opening 652 may be formed by the same lithography method used for the opening 622. In S611, the electrode 660 and the electrode 662 are formed in the opening 650 and the opening 652 respectively.

### EXAMPLE 1

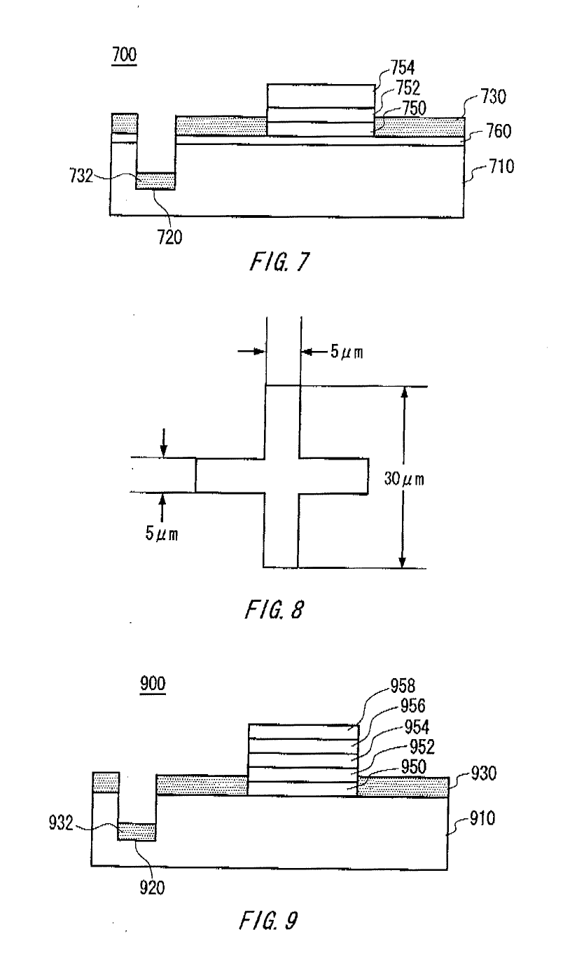

FIG. 7 is a sectional view of a manufactured semiconductor wafer 700. FIG. 8 illustrates a shape of an alignment mark 720 formed on the semiconductor wafer 700. In the semiconductor wafer 700, a GaN buffer layer 750, a GaN crystal 752 and an Al_{0.2}Ga_{0.8}N crystal 754 were formed within an opening formed in an inhibition layer 730 provided on a silicon wafer 710.

An AlN buffer layer 760 having a thickness of 100 nm was formed on the main plane of a Si wafer in the plane orientation (111) and at an off-angle of 0° by a MOCVD method in which the wafer was placed in a reactor at an internal temperature of 900° C. The resulting wafer was removed from the reaction chamber. A photosensitive resin was then applied onto the AlN buffer layer 760. A cross-shaped opening in which the AlN buffer layer 760 is exposed was formed by a photolithography method. Referring to FIG. 8, the opening had a configuration in which two rectangles intersect each other at right angles at their centers. The long sides of the rectangles were 30 μm and the short sides of the rectangles ware 5 μm.

The obtained wafer was then transferred to a reactive ion etching apparatus chamber, the AlN buffer layer 760 exposed in the opening was dry-etched using SF6 gas plasma till the surface of the buffer layer 760 reaches the depth of 5 μm in the Si wafer, and in this way the alignment mark 720 was formed. Subsequently, the photosensitive resin that existed in an area other than the opening was dissolved and removed by using acetone.

Next, silicon oxide was blanket-deposited 50 nm thick on the wafer by a CVD method in order to obtain the inhibition layer 730. The inhibition layer 732 was formed also on the alignment mark 720, Silane and oxygen were used as a source gas. The wafer temperature was 600° C.

A photosensitive resin pattern which has a square-shaped opening was formed on the inhibition layer 730 by a stepper exposure method. At this point, the exposure was performed such that positioning was performed with reference to the alignment mark 720 which had been formed in the above-described way. The wafer was then immersed into a 5% HF solution, and the silicon oxide exposed in the opening in the photosensitive resin was removed by etching in order to expose the MN buffer layer 760.

The photosensitive resin was subsequently removed, and the GaN buffer layer 750 (whose thickness was 100 nm) was grown on the AlN buffer layer 760 exposed in the opening in the inhibition layer 730, by a MOCVD method in which the growth temperature was 900° C. and the pressure in a growth chamber was 30K Pa. The GaN crystal 752 (whose thickness was 2,000 nm), which was the functional crystal, and the Al_{0.2}Ga_{0.8}N crystal 754 (whose thickness was 30 nm) were epitaxially grown by a MOCVD method in which the growth temperature was 1060° C. and the pressure in a growth chamber was 12 M Pa. As a source gas, trimethyl aluminum, trimethyl gallium, and ammonia were used. The resulting wafer was taken out from the MOCVD reactor and then placed in a stepper exposure apparatus.

While aligning the wafer with reference to the alignment mark 720, an opening having a shape of an ohmic electrode was formed in the photosensitive resin on the resulting wafer from the stepper exposure method, Ti was then deposited 150 nm thick and Al was subsequently deposited 1500 nm thick, and a layered structure of Ti/Al metal having the electrode shape was formed. Subsequently, the wafer was annealed for 30 seconds at 800° C. and the ohmic electrode was obtained.

Next, an opening having a shape of a gate electrode was formed in the photosensitive resin by a stepper exposure method while aligning the wafer with reference to the alignment mark 720. Ni was deposited 100 nm thick on the wafer, and Au was subsequently deposited 2,000 nm thick thereon. A layered structure of Ni/Au metal having the electrode shape was then formed by a lift-off method. In this way, the gate electrode was obtained.

Through the above-described processes, it was possible to obtain the semiconductor wafer that has the alignment mark 720 on the Si wafer and in which the relative positions of the semiconductor crystal and the functional members with respect to the alignment mark 720 was accurately defined. Because it is not necessary to separately form the alignment mark 720 used for the formation of the functional members, the productivity can be increased.

### EXAMPLE 2

FIG. 9 is a sectional view of a manufactured semiconductor wafer 900. In the semiconductor wafer 900, a GaAs buffer layer 950, an Al_{0.2}Ga_{0.8}As crystal 952, an In_{0.15}Ga_{0.85}As crystal 954, an Al_{0.2}Ga_{0.8}As crystal 956, and n-GaAs crystal 958 were formed in an opening formed in an inhibition layer 930 provided on a GaAs wafer 910.

A photosensitive resin was applied on the main plane of a GaAs wafer 910 in the plane orientation (001) and at an off-angle of 2°. A cross-shaped opening in which the GaAs wafer 910 was exposed was formed by a photolithography method. The obtained wafer was then transferred to a reactive ion etching apparatus chamber, the GaAs wafer 910 exposed in the opening was dry-etched using SF6 gas plasma untill the surface of the GaAs wafer 910 reaches the depth of 5 μm, and in this way the alignment mark 920 was formed. Subsequently, the photosensitive resin was dissolved and removed by using acetone.

Silicon oxide, which served as the inhibition layer 930, was deposited 50 nm thick on the whole surface of the wafer including the area where the alignment mark 920 was provided by a CVD method. Consequently, the inhibition layer 932 was formed over the alignment mark 920. Silane and oxygen were used as a source gas. The wafer temperature was 600° C.

A photosensitive resin pattern which has a square-shaped opening was formed on the silicon oxide by a stepper exposure method. One side of the square was 20 μm long. At this point, the exposure was performed such that positioning was performed with reference to the alignment mark 920 which had been formed in the above-described way. The wafer was then immersed into a 5% HF solution, and oxide silicon exposed in the opening in the photosensitive resin was removed by etching in order to expose the GaAs wafer 910. The photosensitive resin was subsequently removed, and the GaAs buffer layer 950 (whose thickness was 100 nm) was grown on the GaAs wafer 910 exposed in the opening in the oxide silicon, by a MOCVD method in which the growth temperature was 600° C. and the pressure in a growth chamber was 10K Pa.

Next, the Al_{0.2}Ga_{0.8}As crystal 952 (whose thickness was 2,000 nm), the In_{0.15}Ga_{0.85}As crystal 954 (whose thickness was 20 nm), the Al_{0.2}Ga_{0.8}As crystal 956 (whose thickness was 200 nm), and n-GaAs crystal 958 (whose thickness 20 nm), which were the functional crystals, were epitaxially grown by a MOCVD method in which the growth temperature was 600° C. and the pressure in a growth chamber was 10K Pa. As a source gas, trimethyl aluminum, trimethyl gallium, trimethyl indium, and arsine were used. As an n-type doping source, silane was used.

During growth process of these semiconductor crystals, the alignment mark 920 was covered with the inhibition layer 932 of silicon oxide so that semiconductor crystal was not grown on the alignment mark 920. Accordingly, deformation of the alignment mark 920 due to crystal attached to the alignment mark 920 can be prevented. As a result, the functional members can be formed with a high alignment accuracy using the alignment mark 920 during the formation of the functional members including electrodes and the like which will be hereunder described.

The resulting wafer was taken out from the MOCVD reactor and then placed in a stepper exposure apparatus. A photosensitive resin that has an opening at the position corresponding to a position where an electrode was to be formed was formed by a stepper exposure method while aligning the wafer with reference to the alignment mark 920. Subsequently, the silicon oxide in the opening was dissolved and removed by using a HF solution. The photosensitive resin was then dissolved and removed by using acetone.

A photosensitive resin that has an opening having a shape of an ohmic electrode was formed by a stepper exposure method while aligning the wafer with reference to the alignment mark 920. Ti was then deposited 150 nm thick and Al was subsequently deposited 1,500 nm thick, and a layered structure of Ti/Al metal having the electrode shape was formed. Subsequently, the wafer was annealed for 30 seconds at 800° C. and the ohmic electrode was obtained.

Next, a photosensitive resin that has an opening having a shape of a gate electrode was formed by a stepper exposure method while aligning the wafer with reference to the alignment mark 920. Ni was deposited 100 nm thick on the wafer, and Au was subsequently deposited 2,000 nm thick thereon. A layered structure of Ni/Au metal having the electrode shape was then formed by a lift-off method. In this way, the gate electrode was obtained. Through the above-described processes, a GaAs-based field effect transistor was formed.

Through the above-described processes, it was possible to obtain the semiconductor wafer that had the alignment mark 920 on the GaAs wafer 910 and in which the relative positions of the semiconductor crystal and the functional members with respect to the alignment mark 920 was accurately defined. Because it is not necessary to separately form a alignment mark used for the formation of the functional members, the productivity can be increased.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A method of producing a semiconductor wafer, the method comprising:
forming an alignment mark on a base wafer;
forming, on the base wafer in a region that includes the alignment mark, an inhibition layer for inhibiting crystal growth after forming the alignment mark;
forming, in a region of the inhibition layer where no alignment mark is provided, an opening in which the base wafer is exposed, on the basis of information that indicates a location where the opening is to be formed with reference to the position of the alignment mark; and
growing a semiconductor crystal inside the opening.

2. The method of producing a semiconductor wafer according to claim 1, the method further comprising:
forming at least one of an electrode and a metal wiring line on the semiconductor crystal with reference to the position of the alignment, mark.

3. The method of producing a semiconductor wafer according to claim 1, wherein
in the forming of the opening, a plurality of the openings are formed in the region of the inhibition layer where no alignment mark is provided.

4. The method of producing a semiconductor wafer according to claim 3, wherein
in the forming of the opening, the plurality of openings are formed on the basis of information that indicates locations where the plurality of openings are to be formed with reference to the position of the alignment mark.

5. The method of producing a semiconductor wafer according to claim 3, wherein
in the growing of the semiconductor crystal, the semiconductor crystal is grown in each of the plurality of openings.

6. The method of producing a semiconductor wafer according to claim 5, the method further comprising:
forming a functional member that includes at least one of an electrode and a metal wiring line over the semiconductor crystal in each of the plurality of openings with reference to the position of the alignment mark.

7. The method of producing a semiconductor wafer according to claim 6, wherein
in the forming of the functional member, the functional member is formed by lithography with reference to the position of the alignment mark.

8. The method of producing a semiconductor wafer according to claim 1, wherein
the base wafer is a wafer whose surface is made of a silicon crystal, a wafer whose surface is made of a germanium crystal, or a Group 3-5 compound semiconductor wafer.

9. The method of producing a semiconductor wafer according to claim 1, wherein
in the growing of the semiconductor crystal, a Group 3-5 compound semiconductor crystal or a Group 2-6 compound semiconductor crystal is grown.

10. The method of producing a semiconductor wafer according to claim 1, wherein
the growing of the semiconductor crystal includes:
growing a first semiconductor crystal having a composition of Cₓ₁Si_{y1}Ge_{z1}Sn_{1-x1-y1-z1} (0≦x1<1, 0≦y1≦1, 0≦z1≦1, and 0<x1+y1+z1≦1); and
growing a second semiconductor crystal directly or indirectly on the first semiconductor crystal.

11. The method of producing a semiconductor wafer according to claim 1, wherein
the inhibition layer includes any of silicon oxide, silicon nitride, silicon oxynitride, or aluminum oxide.

12. The method of producing a semiconductor wafer according to claim 1, wherein
in the forming of the alignment mark, the alignment mark is formed on the base wafer by etching the base wafer.

13. The method of producing a semiconductor wafer according to claim 1, wherein
in the forming of the alignment mark, the alignment mark is formed on the base wafer by forming, on the base wafer, at least one metal selected from the group consisting of tantalum, niobium, nickel, tungsten, and titanium.

14. A semiconductor wafer comprising:
a base wafer on which an alignment mark is formed;
a first inhibition layer that inhibits crystal growth and is provided on the base wafer in a region other than a region where the alignment mark is formed, the first inhibition layer having an opening in which the base wafer is exposed;
a second inhibition layer that inhibits crystal growth and is provided over the alignment mark; and
a semiconductor crystal that is grown inside the opening.

15. The semiconductor wafer according to claim 14, wherein
the first inhibition layer has a plurality of the openings, and
the semiconductor wafer has the semiconductor crystal grown in each of the plurality of openings.

16. The semiconductor wafer according to claim 14, wherein
the thickness of the base wafer at the position of the alignment mark is different from the thickness of the base wafer in a region of the base wafer other than the position of the alignment mark, and
the distance between a back surface of the base wafer and a first surface of the first inhibition layer is different from the distance between the back surface of the base wafer and a first surface of the second inhibition layer, wherein the back surface of the base wafer opposes a surface of the base wafer that is in contact with the first inhibition layer, the first surface of the first inhibition layer opposes a second surface of the first inhibition layer that is closer to the base wafer, and the first surface of the second inhibition layer opposes a second surface of the second inhibition layer that is closer to the base wafer.

17. The semiconductor wafer according to claim 16, wherein
the thickness of the base wafer at the position of the alignment mark is smaller than the thickness of the base wafer in the region of the base wafer other than the position of the alignment mark, and
the distance between the back surface of the base wafer and the first surface of the first inhibition layer is larger than the distance between the back surface of the base wafer and the first surface of the second inhibition layer.

18. The semiconductor wafer according to claim 16, wherein
the thickness of the base wafer at the position of the alignment mark is larger than the thickness of the base wafer in the region of the base wafer other than the position of the alignment mark, and
the distance between the back surface of the base wafer and the first surface of the first inhibition layer is smaller than the distance between the back surface of the base wafer and the first surface of the second inhibition layer.
